(19) United States
(12) Patent Application Publication
(10) Pub. No.: US 2011/0057213 A1
(43) Pub. Date: Mar. 10, 2011

(54) III-NITRIDE LIGHT EMITTING DEVICE WITH CURVAT1JRE CONTROL LAYER

(75) Inventors: Linda T. ROMANO, Sunnyvale, CA (US); Parijat Pramil DEB, San Jose, CA (US); Andrew Y. KIM, San Jose, CA (US); John F. KAEDING, San Jose, CA (US)

(73) Assignees: KONINKLIJKE PHILIPS ELECTRONICS N.V., EINDHOVEN (NL); PHILIPS LUMILEDS LIGHTING COMPANY, LLC, SAN JOSE, CA (US)

(21) Appl. No.: 12/555,000

(22) Filed: Sep. 8, 2009

(51) Int. Cl. H01L 33/00

(52) U.S. Cl. 257/94; 438/47; 257/76; 257/103; 257/E33.023

(57) ABSTRACT

A semiconductor structure comprises a III-nitride light emitting layer disposed between an n-type region and a p-type region. The semiconductor structure further comprises a curvature control layer grown on a first layer. The curvature control layer is disposed between the n-type region and the first layer. The curvature control layer has a theoretical a-lattice constant less than the theoretical a-lattice constant of GaN. The first layer is a substantially single crystal layer.

### FIELD OF INVENTION

The present invention relates to a III-nitride device with a curvature control layer.

### BACKGROUND

Semiconductor light-emitting devices including light emitting diodes (LEDs), resonant cavity light emitting diodes (RCLEDs), vertical cavity laser diodes (VCSELs), and edge emitting lasers are among the most efficient light sources currently available. Materials systems currently of interest in the manufacture of high-brightness light emitting devices capable of operation across the visible spectrum include Group III-V semiconductors, particularly binary, ternary, and quaternary alloys of gallium, aluminum, indium, and nitrogen, also referred to as III-nitride materials. Typically, III-nitride light emitting devices are fabricated by epitaxially growing a stack of semiconductor layers of different compositions and dopant concentrations on a sapphire, silicon carbide, III-nitride, composite, or other suitable substrate by metal-organic chemical vapor deposition (MOCVD), molecular beam epitaxy (MBE), or other epitaxial techniques. The stack often includes one or more n-type layers doped with, for example, Si, formed over the substrate, one or more light emitting layers in an active region formed over the n-type layer or layers, and one or more p-type layers doped with, for example, Mg, formed over the active region. Electrical contacts are formed on the n- and p-type regions. III-nitride devices are often formed as inverted or flip chip devices, where both the n- and p-contacts formed on the same side of the semiconductor structure, and light is extracted from the side of the semiconductor structure opposite the contacts.

FIG. 1 illustrates a flip chip III-nitride device described in more detail in U.S. Pat. No. 6,194,742. Beginning at column 3, line 41, the device illustrated in FIG. 1 is described as follows: “An interfacial layer 16 is added to a light-emitting diode or laser diode structure to perform the role of strain engineering and impurity gettering. A layer of AlₓIn_{y}Ga_{1-x-y}N (0≦x≦1, 0≦y≦1) doped with Mg, Zn, Cd can be used for the interfacial layer. Alternatively, when using AlₓIN_{y}Ga_{1-x-y}N with x>0, the interfacial layer may be undoped. The interfacial layer can also include alloys of AlInGaN, AlInGaP, and AlInGaAs, and alloys of GaN, GaP, and GaAs. The interfacial layer 16 is deposited directly on top of the buffer layer 14 prior to the growth of the n-type (GaN:Si) layer 18, active region 10, and the p-type layer 22. The thickness of the interfacial layer varies from 0.01-10.0 μm, having a preferred thickness range of 0.25-1.0 μm. Buffer layer 14 is formed over substrate 12. Substrate 12 may be transparent. Metal contact layer 24A, 24B, are deposited to the p-type and n-type layers 22, 18, respectively.” The preferred embodiment used GaN:Mg and/or AlGaN for the composition of the interfacial layer.

### SUMMARY

It is an object of the present invention to include a curvature control layer in a III-nitride device. In some embodiments, the curvature control layer may reduce the amount of bowing in a III-nitride film grown on a sapphire substrate.

Embodiments of the invention include a semiconductor structure comprising a III-nitride light emitting layer disposed between an n-type region and a p-type region. The semiconductor structure further comprises a curvature control layer grown on a first layer. The curvature control layer is disposed between the n-type region and the first layer. The curvature control layer has a theoretical a-lattice constant less than the theoretical a-lattice constant of GaN. The first layer is a substantially single crystal layer.

### BRIEF DESCRIPTION OF THE DRAWINGS

FIG. 1 illustrates a III-nitride light emitting device with an interfacial layer disposed between a buffer layer and an n-type layer.

FIG. 2 illustrates a portion of a III-nitride light emitting device according to embodiments of the invention.

FIG. 3 illustrates a flip chip light emitting device connected to a mount.

### DETAILED DESCRIPTION

III-nitride devices are often grown on sapphire substrates. The first layers grown on the sapphire, including any buffer or nucleation layers and the first high quality, substantially single crystal layer, are often GaN. GaN grown on sapphire develops stress, due to the lattice and chemical mismatch between the GaN and the sapphire. The amount of stress may depend on the nucleation and coalescence conditions. After growth of the semiconductor structure, as the wafer cools down, additional stress forms in the semiconductor structure, due to the smaller thermal expansion coefficient of GaN (5.6×10⁻⁶/K) as compared to sapphire (7.5×10⁻⁶/K). The stress occurring during cool-down may partially offset the inherent stress due to the lattice and chemical mismatch.

As the thickness of the semiconductor material grown on the sapphire increases, the wafer may bow to partially compensate for the compressive stress in the semiconductor material, such that when viewed from the top, i.e. the surface on which the semiconductor structure is grown, the wafer is convex. For example, a wafer of devices with a semiconductor structure on the order of microns thick may bow on the order of tens of microns, where the bow represents the difference between the height of the edge and the height of the middle of the wafer. Bowing is problematic because the amount of bowing must be compensated for during processing such as photolithography.

In accordance with embodiments of the invention, a layer that at least partially compensates for bowing is included in a III-nitride light emitting device.

FIG. 2 illustrates a portion of a III-nitride device according to embodiments of the invention. In the device illustrated in FIG. 2, a GaN structure 23 is grown first on a growth substrate (not shown in FIG. 2), which may be any suitable growth substrate and which is typically sapphire or SiC. GaN structure 23 may include one or more preparation layers such as buffer layers or nucleation layers. At least one high quality, single crystal layer, often GaN or low AlN composition AlGaN grown at a high temperature, is included in GaN structure 23. GaN structure 23 may include III-nitride layers that are not GaN, such as InGaN, AlGaN, or AlInGaN layers.

A curvature control layer 25 is grown over the single crystal layer included in GaN structure 23. Curvature control layer 25 is a single crystal layer with a theoretical a-lattice constant smaller than the actual a-lattice constant of single crystal layer on which the curvature control layer is grown. In some embodiments, the curvature control layer 25 has a theoretical a-lattice constant smaller than the theoretical a-lattice constant of GaN. In some embodiments, curvature control layer 25 is AlGaN or AlInGaN. When the curvature control layer 25 is grown on GaN or some other material with a larger theoretical lattice constant than curvature control layer 25, such as AlGaN with a smaller AlN composition, curvature control layer 25 is in tension. The tension in curvature control layer 25 may at least partially compensate for the thermal compressive stress induced by the substrate due to cool-down from the growth temperature in GaN structure 23, reducing the amount of bowing in a wafer of devices. In a device without a curvature control layer, the inventors observed a bow of 94 μm. In a comparable device with an AlGaN curvature control layer with 8.5% AlN, the inventors observed a bow of 61 μm.

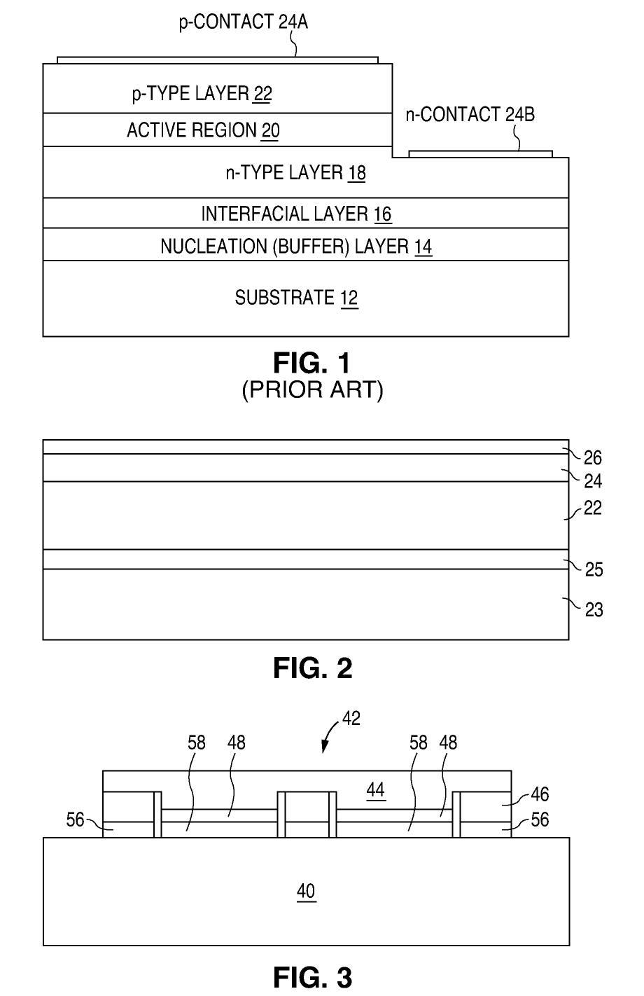

In order for curvature control layer 25 to be in tension, curvature control layer must be grown on a layer of sufficiently high quality that curvature control layer itself is a substantially single crystal layer. In the device illustrated in FIG. 1, interfacial layer 16 is deposited directly on a buffer layer 14, which is typically an amorphous layer grown at low temperature. An interfacial layer 16 grown on a buffer layer as described in U.S. Pat. No. 6,194,742 will typically not be a strained, pseudomorphic layer, which is necessary for the layer to reduce bowing.

The AlN composition in an AlGaN curvature control layer 25 may be, for example, less than 30% in some embodiments, between 2% and 15% in some embodiments, between 6% and 10% in some embodiments, between 7% and 9% in some embodiments, 7.5% in some embodiments, and 8.5% in some embodiments. At compositions greater than 10%, in some devices the inventors observed buried cracking in the curvature control layer, which actually increased the amount of bowing. In some embodiments, the AlN composition in an AlInGaN curvature control layer 25 may be the same as the AlN compositions recited above for an AlGaN curvature control layer. Since the lattice constant of InN is large compared to the lattice constant of GaN, the addition of InN would reduce the amount of tension in the curvature control layer, thus the InN composition is generally kept small. For example, in some embodiments, the InN composition in an AlInGaN curvature control layer may be on the order of a few percent. In some embodiments, the AlN composition in an AlInGaN curvature control layer may be greater than the AlN compositions described above for an AlGaN curvature control layer, in order to at least partially compensate for the reduction in tension caused by the addition of InN.

The theoretical lattice constant of the curvature control layer 25, calculated according to Vegard's law from the a-lattice constants of AlN (3.111 Å), GaN (3.189 Å), inN (3.533 Å), may be between 3.111 and 3.189 Å in some embodiments, between 3.165 and 3.188 Å in some embodiments, between 3.180 and 3.184 Å in some embodiments, and between 3.182 and 3.183 Å in some embodiments. For an AlₓN_{y}Ga_{1-x-y}N layer, the lattice constant may be calculated according to a_{AlInGAN}=(a_{AlN})x+(a_{InN})_{y}+(a_{GaN})(1-x-y).

Curvature control layer 25 is thick enough to create enough tension to reduce the bow, but thin enough that the curvature control layer does not crack. Curvature control layer may be, for example, 200 Å to just below the cracking limit thick in some embodiments, 500 to 1500 Å thick in some embodiments, 0.5 to 5 μm thick in some embodiments, and 1 to 2 μm thick in some embodiments. As the composition of AlN in an AlGaN layer increases, the theoretical lattice constant decreases. Accordingly, as the composition of AlN increases, the thickness to which the AlGaN layer can be grown without cracking decreases.

The amount of tension in the curvature control layer, and therefore the ability of the curvature control layer to reduce bowing, is the product of the thickness of the curvature control layer and the strain caused by the difference between the theoretical lattice constant of the curvature control layer and the actual lattice constant of the layer on which the curvature control layer is grown. To achieve a given amount of tension, a highly strained curvature control layer may be thinner than a less strained curvature control layer. In some embodiments, the curvature control layer is grown on a GaN layer. The actual in-plane lattice constant of such a GaN layer may depend on the growth conditions, and may vary, for example, between 3.184 and 3.189 Å. If a GaN layer on which the curvature control layer has a relatively small in-plane lattice constant, the AlN composition and/or the thickness of the curvature control layer may be smaller than if the GaN layer on which the curvature control layer is grown has a relatively large in-plane lattice constant.

In some embodiments, the curvature control layer is grown at a slower rate than GaN structure 23.

Curvature control layer 25 is usually not intentionally doped, though it may be doped with an n-type or p-type dopant.

A semiconductor structure including an n-type region, a light emitting or active region, and a p-type region is grown over the curvature control layer. An n-type region 22 is grown first over the substrate. N-type region 22 may include multiple layers of different compositions and dopant concentration including, for example, preparation layers such as buffer layers or nucleation layers, which may be n-type or not intentionally doped, release layers designed to facilitate later release of the growth substrate or thinning of the semiconductor structure after substrate removal, and n- or even p-type device layers designed for particular optical or electrical properties desirable for the light emitting region to efficiently emit light.

In some embodiments, curvature control layer 25 is sandwiched between two high quality, substantially single crystal layers. The dislocation density in one or both of the layers sandwiching curvature control layer 25 may be between 10⁵ and 10⁹ cm⁻² in some embodiments.

A light emitting or active region 24 is grown over n-type region 22. Examples of suitable light emitting regions include a single thick or thin light emitting layer, or a multiple quantum well light emitting region including multiple thin or thick quantum well light emitting layers separated by barrier layers. For example, a multiple quantum well light emitting region may include multiple light emitting layers, each with a thickness of 25 Å or less, separated by barriers, each with a thickness of 100 Å or less. In some embodiments, the thickness of each of the light emitting layers in the device is thicker than 50 Å.

A p-type region 26 is grown over light emitting region 24. Like the n-type region, the p-type region may include multiple layers of different composition, thickness, and dopant concentration, including layers that are not intentionally doped, or n-type layers.

FIG. 3 illustrates an LED 42 connected to a mount 40. A p-contact 48, often a reflective silver contact, is formed on the p-type region. Before or after forming the p-contact, portions of the n-type region are exposed by etching away portions of the p-type region and the light emitting region. The semiconductor structure, including the n-type region 22, light emitting region 24, and p-type region 26 is represented by structure 44 in FIG. 3. N-contact 46 is formed on the exposed portions of the n-type region. Since the n-contact 46 is formed on n-type region 22, curvature control layer 25 is not in the path of current in the device and therefore does not alter the electrical properties of the device, regardless of the composition of curvature control layer 25.

LED 42 is bonded to mount 40 by n- and p-interconnects 56 and 58. Interconnects 56 and 58 may be any suitable material, such as solder or other metals, and may include multiple layers of materials. In some embodiments, interconnects include at least one gold layer and the bond between LED 42 and mount 40 is formed by ultrasonic bonding.

During ultrasonic bonding, the LED die 42 is positioned on a mount 40. A bond head is positioned on the top surface of the LED die, often the top surface of a sapphire growth substrate in the case of a III-nitride device grown on sapphire. The bond head is connected to an ultrasonic transducer. The ultrasonic transducer may be, for example, a stack of lead zirconate titanate (PZT) layers. When a voltage is applied to the transducer at a frequency that causes the system to resonate harmonically (often a frequency on the order of tens or hundreds of kHz), the transducer begins to vibrate, which in turn causes the bond head and the LED die to vibrate, often at an amplitude on the order of microns. The vibration causes atoms in the metal lattice of a structure on the LED 42 to interdiffuse with a structure on mount 40, resulting in a metallurgically continuous joint. Heat and/or pressure may be added during bonding.

After bonding LED die 42 to mount 40, the growth substrate on which the semiconductor layers were grown may be removed, for example by laser lift off, etching, or any other technique suitable to a particular growth substrate. After removing the growth substrate, the semiconductor structure may be thinned, for example by photoelectrochemical etching, and/or the surface may be roughened or patterned, for example with a photonic crystal structure. All or part of GaN structure 23 and curvature control layer 25 may remain in the device or may be removed during thinning after removing the growth substrate. A lens, wavelength converting material, or other structure known in the art may be disposed over LED 42 after substrate removal.

Having described the invention in detail, those skilled in the art will appreciate that, given the present disclosure, modifications may be made to the invention without departing from the spirit of the inventive concept described herein. Therefore, it is not intended that the scope of the invention be limited to the specific embodiments illustrated and described.

What is being claimed is:

1. A device comprising:
a semiconductor structure comprising:
a III-nitride light emitting layer disposed between an n-type region and a p-type region; and
a curvature control layer grown on a first layer, wherein:
the curvature control layer has a theoretical a-lattice constant less than a theoretical a-lattice constant of GaN;
the first layer is a substantially single crystal layer; and
the curvature control layer is disposed between the n-type region and the first layer.

2. The device of claim 1 wherein the curvature control layer comprises aluminum.

3. The device of claim 1 wherein the curvature control layer is AlGaN.

4. The device of claim 3 wherein the curvature control layer has an AlN composition greater than 0% and less than 10%.

5. The device of claim 1 wherein the curvature control layer is AlInGaN.

6. The device of claim 1 wherein the curvature control layer has a theoretical a-lattice constant between 3.165 and 3.188 Å.

7. The device of claim 1 wherein the curvature control layer has a theoretical a-lattice constant between 3.180 and 3.184 Å.

8. The device of claim 1 wherein the curvature control layer is between 0.5 and 5 μm thick.

9. The device of claim 1 wherein the curvature control layer is between 1 and 2 μm thick.

10. The device of claim 1 wherein the curvature control layer is not intentionally doped.

11. The device of claim 1 further comprising an n-contact disposed on the n-type region and a p-contact disposed on the p-type region, wherein both the n- and p-contacts are formed on a same side of the semiconductor structure.

12. The device of claim 1 wherein a composition and thickness of the curvature control layer are selected to at least partially compensate for thermal compressive stress induced in the first layer during cool-down from an elevated growth temperature.

13. A method comprising:
growing on a substrate a semiconductor structure comprising:
a curvature control layer grown on a first layer; and
a III-nitride light emitting layer disposed between an n-type region and a p-type region; wherein:
the curvature control layer has a theoretical a-lattice constant less than a theoretical a-lattice constant of GaN;
the first layer is a substantially single crystal layer; and
the curvature control layer is disposed between the n-type region and the first layer.

14. The method of claim 13 wherein the curvature control layer is grown at a slower rate than the first layer.

15. The method of claim 13 wherein a composition and thickness of the curvature control layer are selected to at least partially compensate for thermal compressive stress induced in the first layer during cool-down from an elevated growth temperature.
